(19) United States
(12) Patent Application Publication
(10) Pub. No.: US 2021/0025951 A1
(43) Pub. Date: Jan. 28, 2021

(54) Systems and Methods for MOKE Metrology with Consistent MRAM Die Orientation

(71) Applicant: KLA Corporation, Milpitas, CA (US)

(72) Inventor: Ferenc Z. Vajda, Winchester, MA (US)

(21) Appl. No.: 16/935,432

(22) Filed: Jul. 22, 2020

Related U.S. Application Data
(60) Provisional application No. 62/877,908, filed on Jul. 24, 2019.

(51) Int. Cl. G01R 33/032; H01L 27/22

(52) U.S. Cl. CPC G01R 33/0325; H01L 27/222

(57) ABSTRACT

A metrology tool includes a magnet to generate a magnetic field and a stage system to position a plurality of MRAM dies on an MRAM wafer in the magnetic field. The stage system includes a chuck on which to mount the MRAM wafer. The metrology tool further includes optics to provide a laser beam and direct the laser beam to be incident upon respective MRAM dies positioned in the magnetic field. The metrology tool additionally includes a detector to receive the laser beam as reflected by the respective MRAM dies and to measure rotation of the polarization of the reflected laser beam. The metrology tool is configurable to provide each MRAM die on the MRAM wafer with a common orientation with respect to the polarization of the laser beam.

### RELATED APPLICATION

This application claims priority to U.S. Provisional Patent Application No. 62/877,908, filed on Jul. 24, 2019, which is incorporated by reference in its entirety for all purposes.

### TECHNICAL FIELD

This disclosure relates to the magneto-optic Kerr effect (MOKE), and more specifically to MOKE metrology for characterizing magnetic random-access memory (MRAM).

### BACKGROUND

The magneto-optic Kerr effect (MOKE) refers to the rotation of the polarization of light when reflected from a magnetic surface. MOKE measurements can be used to characterize both continuous and patterned thin films. For example, MOKE measurements are used to characterize magnetic random-access memory (MRAM) devices, in which magnetic thin films are patterned into bit cells. MOKE measurements can be made before and after patterning, to measure the impact of the patterning on magnetic properties of the devices. MOKE measurements are also referred to as MOKE metrology.

FIG. 1 is a schematic view of a MOKE measurement system 100. The MOKE measurement system 100 includes a magnet 102 with a first pole piece 104-1 and a second pole piece 104-2. The magnet 102, which is an electromagnet, also includes respective conductive coils 106-1 and 106-2 wrapped around the pole pieces 104-1 and 104-2. A wafer 110 is positioned in the magnet between the pole pieces 104-1 and 104-2. (When the wafer 110 is positioned between the pole pieces 104-1 and 104-2, portions of the wafer may extend sideways beyond the bottom edges of the pole pieces 104-1 and 104-2, as shown in FIG. 1.) The wafer 110 may be an MRAM wafer (e.g., MRAM wafer 300, FIG. 3) that is divided into a plurality of MRAM dies (e.g., MRAM dies 302, FIG. 3). The magnet 102 generates a magnetic field (H) 108 that is normal (i.e., perpendicular) to the surface of the wafer 110. If the wafer 110 is an MRAM wafer, then the magnetic field 108 is perpendicular to the surfaces of the MRAM dies on the wafer.

The MOKE measurement system 100 also includes optics to provide a laser beam 114 and direct the laser beam 114 to be incident upon the wafer 110 with the wafer 110 positioned in the magnet between the pole pieces 104-1 and 104-2. The laser beam 114 is normally incident on (i.e., perpendicular to the surface of) the wafer 110. The optics include a laser 112 to generate the laser beam 114, a polarizer 116 to polarize the laser beam 114, and mirrors 118-1 and 118-2 to direct the laser beam 114 so that it is incident upon the wafer 110. While FIG. 1 shows two mirrors 118-1 and 118-2, the number and arrangement of mirrors 118 may be different for different implementations of the MOKE measurement system 100. The laser beam 114 as polarized by the polarizer 116 has a specific polarization (e.g., with a specific a plane of polarization).

To take MOKE measurements, the laser beam 114 is provided and directed onto the wafer 110 while the magnet 102 generates the magnetic field 108 (e.g., while current is applied to the conductive coils 106-1 and 106-2), with the wafer 110 positioned in the magnetic field 108. The laser beam 114 is reflected by the wafer 110 (e.g., by an MRAM array 304 in an MRAM die 302, FIG. 3), producing a reflected laser beam 120 that is received by a detector 122. The polarization (e.g., plane of polarization) of the reflected laser beam 120 is rotated with respect to the polarization (e.g., plane of polarization) of the laser beam 114, due to the MOKE. The detector 122 measures this rotation. The detector 122 includes an analyzer that is used in conjunction with the polarizer 116 to measure the rotation. Various magnetic properties of interest (e.g., coercivities, saturation magnetization, exchange coupling, domain structure, spin polarization, switching curves, and/or hysteresis curves) can be determined based on these MOKE measurements.

The MOKE measurement system 100 measures the polar MOKE, with the magnetic field 108 and laser beam 114 both normal to the surface of the wafer 110. Polar MOKE measurements are useful for characterizing MRAM devices with perpendicular-type magnetic-tunnel-junction (MTJ) stacks, such as spin-torque-transfer (STT) MRAM devices.

FIG. 2 is a perspective view of a stage system 200 that is traditionally used to position the wafer 110 in the magnet 102, between the pole pieces 104-1 and 104-2 (FIG. 1). The stage system 200 includes a rotational chuck 202 on which the wafer 110 can be mounted. A motor 208 rotates the chuck 202 about a central axis of the chuck 202. The central axis is the rotational axis of the chuck 202. The chuck 202 is coupled to a translational stage 204 (largely obscured by the chuck in FIG. 2) that can be moved (i.e., translated) along rails 206 by a motor 210. The stage system 200 thus has a single axis of translation, in the direction of (i.e., parallel to) the rails 206, along which the chuck 202 can be translated. Through a combination of rotation of the chuck 202 and translation of the chuck 202 along the single axis of translation, different regions of the wafer 110 (e.g., each die on the wafer 110) are successively positioned in the laser beam 114 (i.e., are positioned to receive the laser beam) and MOKE measurements for the regions (e.g., dies) are taken accordingly.

FIG. 3 is a hypothetical example of an MRAM wafer 300 divided into a plurality of MRAM dies 302. Each MRAM die 302 is a fully or partially fabricated MRAM device that includes an array 304 of MRAM bit cells. (In FIG. 3, the array 304 is only shown for a single MRAM die 302, for simplicity.) The MRAM wafer 300 can be mounted on the chuck 202 (FIG. 2) and positioned in the magnet 102 of the MOKE measurement system 100, between the pole pieces 104-1 and 104-2 (FIG. 1). In FIG. 3, the wafer 300 has been positioned so that a beam spot 306 for the laser beam 114 (FIG. 1) is incident on an array 304 of an MRAM die 302. The beam spot 306 may have a spot size on the order of one millimeter or substantially less (e.g., on the order of microns). By rotating the chuck 202 and translating the chuck 202 along the single axis of translation for the stage system 200 (FIG. 2), each MRAM die 302 can be successively positioned so that the beam spot 306 is successively incident on the MRAM dies 302. Each MRAM die 302 can thereby receive and reflect the laser beam 114 while positioned in the magnetic field 108 (FIG. 1), and MOKE measurements for each MRAM die 302 can be taken accordingly.

### SUMMARY

The successive positioning of each MRAM die 302 on the MRAM wafer 300 in the beam spot 306 (FIG. 3) using the stage system 200 (FIG. 2), with its single axis of translation, causes different MRAM dies 302 on the MRAM wafer 300 to have different orientations with respect to the polarization of the laser beam 114 (e.g., with respect to the plane of polarization of the laser beam 114). The orientation of MRAM dies 302 with respect to the polarization of the laser beam 114 thus varies depending on the location of the MRAM dies 302 on the MRAM wafer 300. The signal-to-noise ratio for MOKE measurements of MRAM dies varies, however, depending on the MRAM-die orientation with respect to the polarization of the laser beam 114. This wafer-location dependence of the relative orientation results from the patterning of the magnetic films on the MRAM dies to form bit cells, which exposes portions of underlying layers (e.g., of the bottom electrode). Some relative orientations cause drastic reduction of the signal-to-noise ratio. For example, the signal-to-noise ratio for some relative orientations may fall below a threshold for performing MOKE measurements. As a result, MOKE measurements may be limited to sampling a portion of MRAM dies on a wafer and may be noisier for some dies than for others.

Accordingly, there is a need for methods and systems of measuring the MOKE for MRAM dies in which respective MRAM dies (e.g., all MRAM dies) on an MRAM wafer are positioned such that they have a common orientation with respect to the polarization of the laser beam used for the MOKE measurements.

In some embodiments, a metrology tool includes a magnet to generate a magnetic field. The metrology tool also includes a stage system to position a plurality of MRAM dies on an MRAM wafer in the magnetic field. The stage system includes a chuck on which to mount the MRAM wafer. The metrology tool further includes optics to provide a laser beam and direct the laser beam to be incident upon respective MRAM dies on the MRAM wafer with the respective MRAM dies positioned in the magnetic field. The laser beam has a polarization. The metrology tool additionally includes a detector to receive the laser beam as reflected by the respective MRAM dies on the MRAM wafer and to measure the rotation of the polarization of the reflected laser beam. The metrology tool is configurable to provide each MRAM die on the MRAM wafer with a common orientation with respect to the polarization of the laser beam when the laser beam is incident on the MRAM die with the MRAM die positioned in the magnetic field.

In some embodiments, a method performed in a metrology tools includes generating a magnetic field and positioning an MRAM wafer that includes a plurality of MRAM dies in the magnetic field. With the MRAM wafer positioned in the magnetic field, a laser beam is provided to be incident upon the MRAM wafer. The laser beam has a polarization. Respective MRAM dies on the MRAM wafer are successively positioned so that the laser beam is successively incident on the respective MRAM dies while the respective MRAM dies are positioned in the magnetic field. Each of the respective MRAM dies is oriented with a common orientation with respect to the polarization of the laser beam when the laser beam is incident on the MRAM die. For each of the respective MRAM dies, rotation of the polarization of the laser beam as reflected by the MRAM die is measured.

In some embodiments, a metrology tool includes a magnet to generate a magnetic field. The metrology tool also includes a stage system to position a plurality of MRAM dies on an MRAM wafer in the magnetic field. The stage system includes a chuck on which to mount the MRAM wafer. The metrology tool further includes optics to provide a laser beam and direct the laser beam to be incident upon respective MRAM dies on the MRAM wafer with the respective MRAM dies positioned in the magnetic field. The laser beam has a polarization. The metrology tool additionally includes a detector to receive the laser beam as reflected by the respective MRAM dies on the MRAM wafer and to measure rotation of the polarization of the reflected laser beam. The metrology tool further includes one or more processors and memory storing one or more programs for execution by the one or more processors. The one or more programs include instructions for providing each MRAM die on the MRAM wafer with a common orientation with respect to the polarization of the laser beam when the laser beam is incident on the MRAM die with the MRAM die positioned in the magnetic field.

### BRIEF DESCRIPTION OF THE DRAWINGS

For a better understanding of the various described implementations, reference should be made to the Detailed Description below, in conjunction with the following drawings. The drawings may not be to scale.

FIG. 1 is a schematic view of a MOKE measurement system.

FIG. 2 is a perspective view of a stage system to rotate a wafer and translate the wafer along one axis of translation.

FIG. 3 is a hypothetical example of an MRAM wafer divided into a plurality of MRAM die, with a laser beam incident on a respective MRAM die.

FIG. 4 is a perspective view of a stage system to rotate a wafer and translate the wafer along two axes of translation, in accordance with some embodiments.

FIG. 5 is a schematic view of a MOKE measurement system, in accordance with some embodiments.

FIGS. 6 and 7 are examples of MOKE measurements for an MRAM array on an MRAM die.

FIG. 8 is a flowchart showing a method of characterizing MRAM dies using the MOKE, in accordance with some embodiments.

FIG. 9 is a block diagram of a MOKE metrology system in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

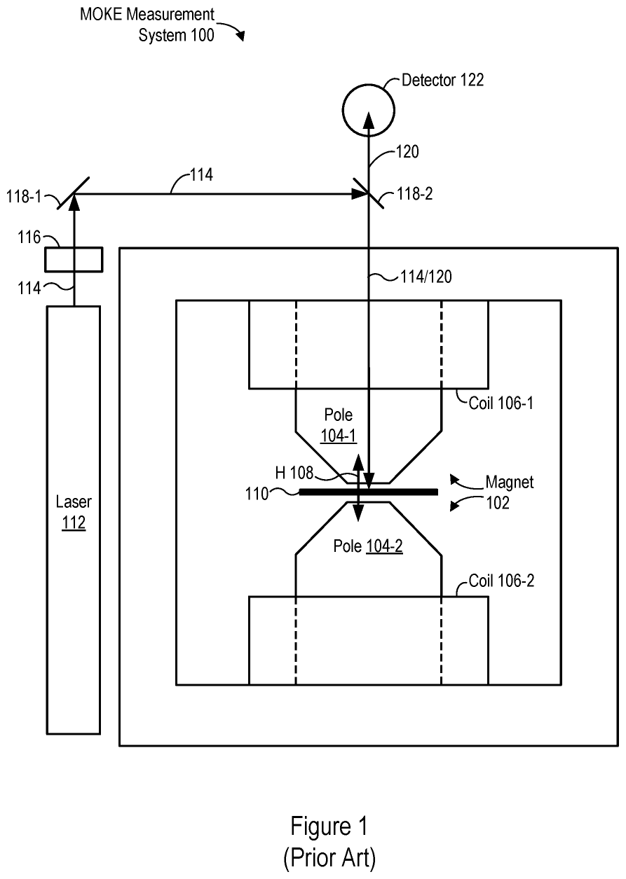

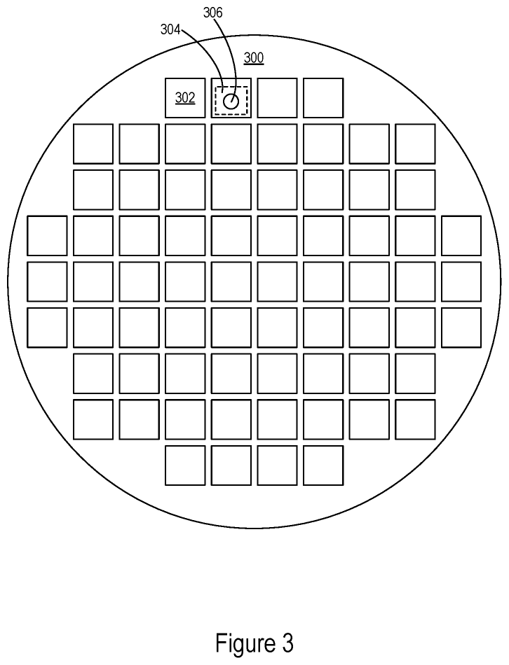

Methods and systems for performing MOKE measurements on MRAM dies are disclosed that allow respective MRAM dies (e.g., all MRAM dies) on an MRAM wafer (e.g., MRAM wafer 300, FIG. 3) to be positioned for MOKE measurements with a common orientation with respect to the polarization (e.g., with respect to the plane of polarization) of a laser beam (e.g., laser beam 114, FIG. 1) used for the MOKE measurements. Such methods and systems ensure that MOKE measurements for the respective MRAM dies may be performed with a sufficient signal-to-noise ratio. For example, such methods and systems may ensure that all MRAM dies on an MRAM wafer, or all MRAM dies identified as candidates for inspection on the MRAM wafer, may be characterized (i.e., inspected) using MOKE measurements.

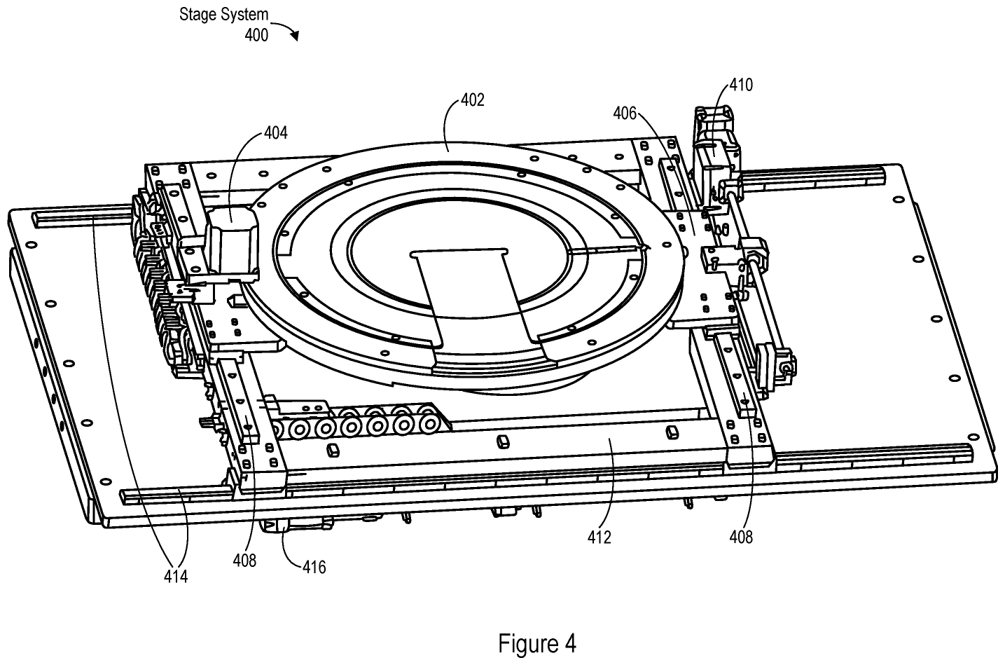

FIG. 4 is a perspective view of a stage system 400 that may be used in a MOKE measurement system to position respective MRAM dies (e.g., all MRAM dies) on an MRAM wafer (e.g., MRAM wafer 300, FIG. 3) in a magnetic field (e.g., H 108, FIG. 1). The stage system 400 may orient the respective MRAM dies (e.g., all MRAM dies) on the MRAM wafer with a common orientation with respect to the polarization (e.g., to the plane of polarization) of the MOKE measurement system's laser beam (e.g., laser beam 114, FIG. 1), in accordance with some embodiments. For example, the stage system 400 may be used in a polar MOKE measurement system (e.g., the MOKE measurement system 100, FIG. 1), longitudinal MOKE measurement system, or transverse MOKE measurement system. The common orientation may be an orientation that has been predetermined to provide a sufficient signal-to-noise ratio for MOKE measurements. The stage system 400 includes a rotational chuck 402 on which a wafer (e.g., wafer 110, FIG. 1; wafer 300, FIG. 3) can be mounted. A motor 404 rotates the chuck 402 about a rotational axis (e.g., a central axis) of the chuck 402. The chuck 402 is coupled to a first translational stage 406 that can be moved (i.e., translated) along rails 408 by a motor 410. The first translational stage 406 is coupled to a second translational stage 412 that that can be moved (i.e., translated) along rails 414 by a motor 416. The first translational stage 406 couples the chuck 402 to the second translational stage 412. Movement of the first translational stage 406 and the second translational stage 412 translates the chuck 402 accordingly: moving the first translational stage 406 translates the chuck in the direction of the rails 408, and moving the second translational stage 412 translates the first translational stage 406 and the chuck 402 in the direction of the rails 414.

The stage system 400 thus has two axes of translation: a first axis of translation in the direction of (i.e., parallel to) the rails 408, along which the first stage 406 can translate the chuck 402, and a second axis of translation in the direction of (i.e., parallel to) the rails 414, along which the second translational stage 412 can translate the first translational stage 406 and the chuck 402. The motor 410 moves the first translational stage 406 along the first translational axis. The motor 416 moves the second translational stage 412 along the second axis of translation. In some embodiments, the first and second axes of translation are perpendicular. For example, the rails 408 are perpendicular to the rails 414 (to within manufacturing tolerances).

By mounting an MRAM wafer on the chuck 402, positioning the MRAM wafer as mounted on the chuck 402 in a magnet of a MOKE measurement system (e.g., between the pole pieces 104-1 and 104-2 of the magnet 102, FIG. 1), and performing a combination of rotating the chuck 402 and translating the chuck 402 along the first and second axes of translation, respective MRAM dies (e.g., each MRAM die) on the MRAM wafer may be successively positioned in the magnet's magnetic field (e.g., H 108, FIG. 1) with a common orientation with respect to the polarization of the MOKE measurement system's laser beam when the laser beam is successively incident on the MRAM dies. For example, the common orientation may be achieved by rotating the chuck 402 and thus the MRAM wafer. Respective MRAM dies may then be successively positioned, with the common orientation, to receive the laser beam by translating the chuck 402, and thus the MRAM wafer, along the first and second axes of translation.

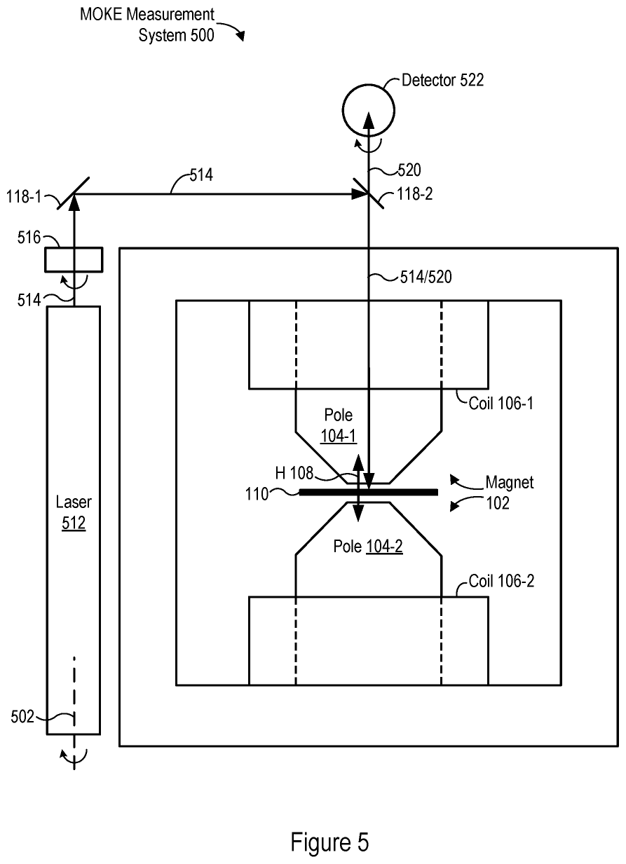

The common orientation may alternately be achieved by rotating optical components. FIG. 5 is a schematic view of a MOKE measurement system 500, in accordance with some embodiments. The MOKE measurement system 500 includes the components of the MOKE measurement system 100 (FIG. 1), with the laser 112, polarizer 116, and detector 122 being replaced by a laser 512, polarizer 516, and detector 522 that are rotatable about their respective longitudinal axes: the laser 512 is rotatable about its longitudinal axis 502, the polarizer 516 is rotatable about a longitudinal axis parallel to the optical path of the laser beam 514, and the detector 522 (e.g., an analyzer within the detector 522) is rotatable about a longitudinal axis parallel to the optical path of the reflected laser beam 520. In some embodiments, the laser 512 and polarizer 516 are configured to rotate by equal amounts (e.g., to rotate together). In some embodiments, the detector 522 (e.g., the analyzer within the detector 522) is configured to rotate in accordance with the rotation of the laser 512 and polarizer 516. For example, the detector 522 (e.g., the analyzer within the detector 522) is configured to rotate by an equal amount as the laser 512 and polarizer 516 (e.g., to rotate together with the laser 512 and polarizer 516).

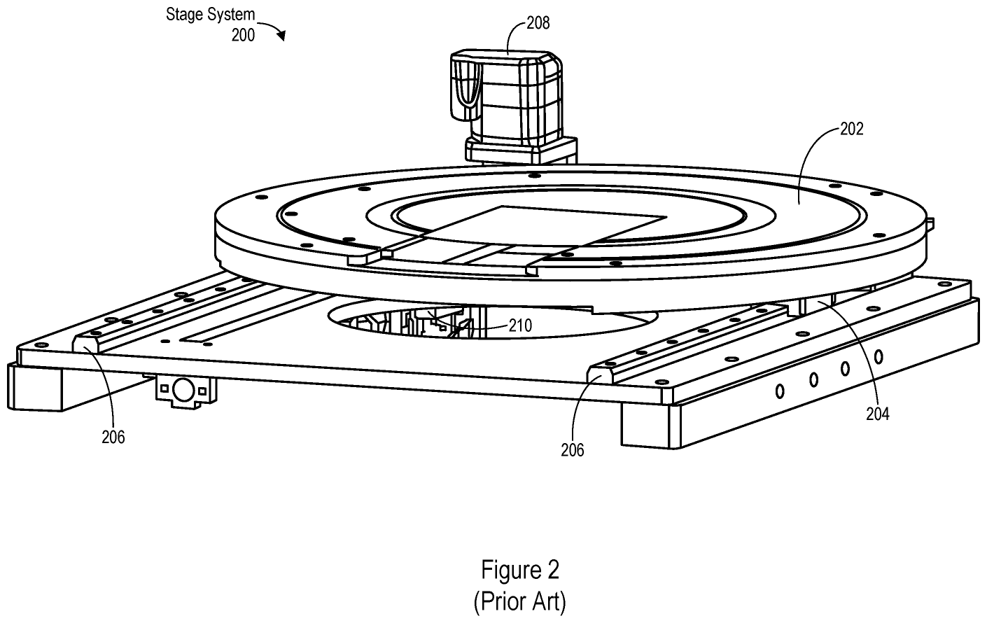

Rotating the laser 512 and polarizer 516 rotates the polarization of the laser beam 514 (e.g., rotates the plane of polarization of the laser beam 514). The laser 512 and polarizer 516 may be rotated to maintain a common orientation of different MRAM dies with respect to the polarization of the laser beam 514 when performing MOKE measurements for the different MRAM dies. For example, different MRAM dies 302 on an MRAM wafer 300 may be successively positioned in the magnetic field 108, between the first and second pole pieces 104-1 and 104-2, using the stage system 200 (FIG. 2), so that the laser beam 514 is successively incident on the different MRAM dies 302. The stage system 200, with its single translational axis, causes the different MRAM dies 302 to have different absolute orientations when positioned to receive the laser beam 514 in this manner. Rotating the laser 512 and polarizer 516 allows the different MRAM dies 302 to have a common orientation with respect to the polarization of the laser beam 514, despite the different absolute orientations of the different MRAM dies 302. Rotating the detector 522 (e.g., the analyzer within the detector 522) in accordance with the rotation of the laser 512 and polarizer 516 allows the detector 522 to measure the rotation of the polarization for the reflected laser beam 520 (i.e., as measured with respect to the polarization of the incident laser beam 514).

In still other alternatives, the common orientation may be achieved by holding the MRAM wafer stationary and moving all or a portion of the MOKE measurement system. For example, the magnet 102 and all or a portion of the optics of the MOKE measurement system 100 (FIG. 1) may be moved while the stage system on which the MRAM wafer is mounted is stationary.

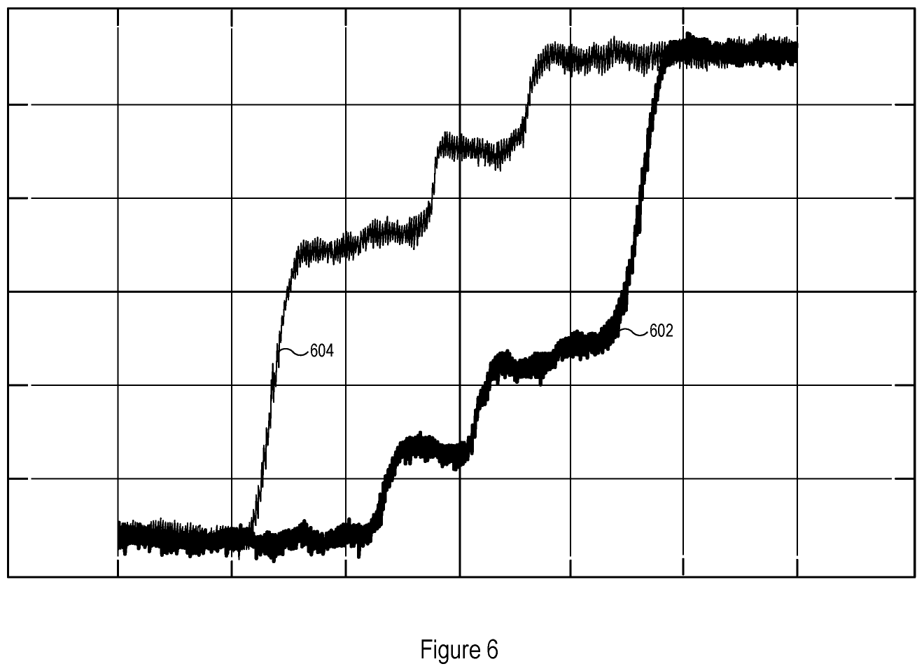

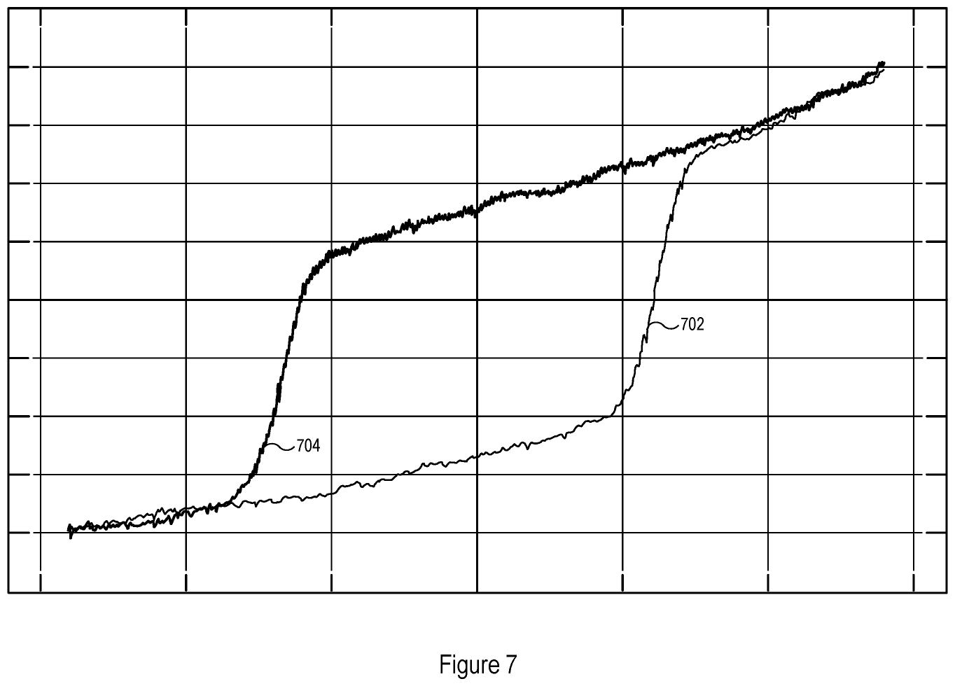

FIGS. 6 and 7 are examples of MOKE measurements for an MRAM array on an MRAM die. FIG. 6 shows a high-field, full-stack measurement for the MRAM array, while FIG. 7 shows a low-field, free-layer measurement for the MRAM array. The x-axes of FIGS. 6 and 7 are the magnetic field strength (e.g., in Oe), while the y-axes are Kerr rotation in arbitrary units. In FIG. 6, curve 602 is measured for an increasing magnetic field and curve 604 is measured for a decreasing magnetic field. In FIG. 7, curve 702 is measured for an increasing magnetic field and curve 704 is measured for a decreasing magnetic field. Magnetic properties of interest may be extracted from the curves 602, 604, 702, and 704 using known techniques. These types of curves may be obtained using a MOKE measurement system such as the MOKE measurement system 100 (FIG. 1) or 500 (FIG. 5).

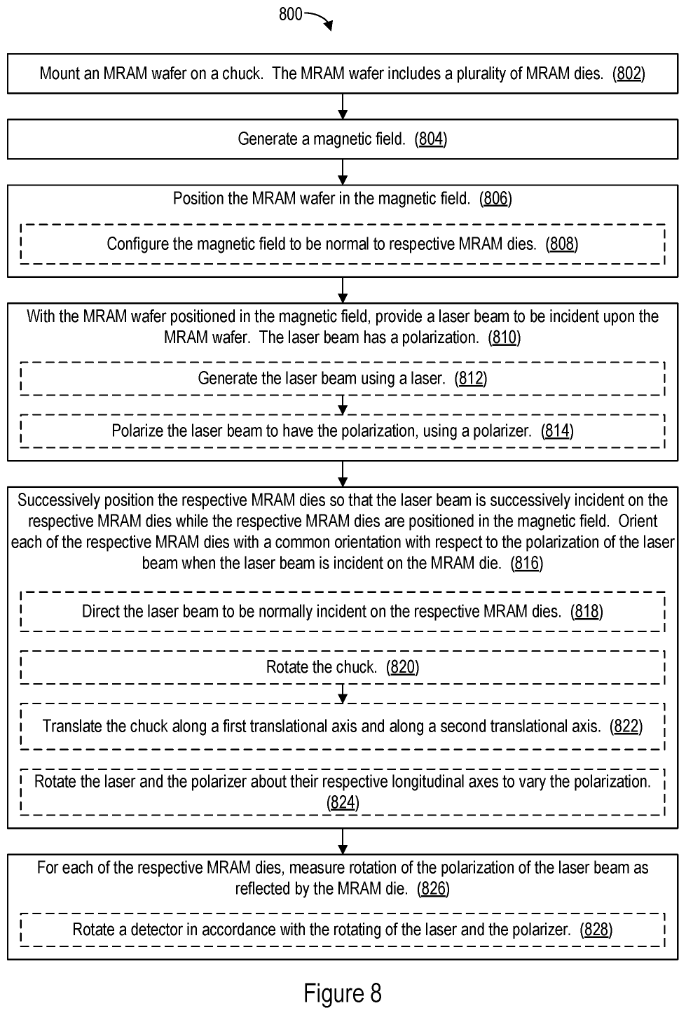

FIG. 8 is a flowchart showing a method 800 of characterizing MRAM dies using the MOKE, in accordance with some embodiments. In the method 800, an MRAM wafer (e.g., MRAM wafer 300, FIG. 3) is mounted (802) on a chuck. The MRAM wafer includes a plurality of MRAM dies (e.g., MRAM dies 302, FIG. 3).

A magnetic field is generated (804). The MRAM wafer is positioned (806) in the magnetic field. For example, the MRAM wafer is positioned between the first pole piece 104-1 and the second pole piece 104-2 (FIG. 1 or 5). In some embodiments, the magnetic field (e.g., H 108, FIG. 1 or 5) is configured (808) to be normal to respective MRAM dies on the MRAM wafer.

With the MRAM wafer positioned in the magnetic field, a laser beam (e.g., laser beam 114, FIG. 1; laser beam 514, FIG. 5) is provided (810) to be incident upon the MRAM wafer. The laser beam has a polarization with an orientation. The laser beam is generated (812) using a laser (e.g., laser 112, FIG. 1; laser 512, FIG. 5) and polarized (814) to have the polarization using a polarizer (e.g., polarizer 116, FIG. 1; polarizer 516, FIG. 5).

The respective MRAM dies (e.g., each MRAM die on the MRAM wafer) are successively positioned (816) so that the laser beam is successively incident on the respective MRAM dies while the respective MRAM dies are positioned in the magnetic field. Each of the respective MRAM dies (e.g., each MRAM die on the wafer) is oriented (816) with a common orientation with respect to the polarization of the laser beam (e.g., with respect to the plane of polarization of the laser beam) when the laser beam is incident on the MRAM die. The common orientation may be an orientation that has been predetermined to provide a sufficient signal-to-noise ratio for MOKE measurements. The respective MRAM dies reflect the laser beam.

In some embodiments, the laser beam is directed (818) to be normally incident on the respective MRAM dies (e.g., as shown in FIGS. 1 and 5).

In some embodiments, successively positioning the respective MRAM dies includes rotating (820) the chuck and translating (822) the chuck along a first translational axis and along a second translational axis. For example, the chuck 402 is translated along the first and second translational axes of the stage system 400 (FIG. 4). The first and second translational axes may be perpendicular (to within manufacturing tolerances).

In some embodiments, orienting each of the respective MRAM dies with the common orientation includes rotating (824) the laser (e.g., laser 512, FIG. 5) and the polarizer (e.g., polarizer 516, FIG. 5) about their respective longitudinal axes to vary the polarization of the incident laser beam. For example, orienting the MRAM dies by rotating the laser and polarizer is performed in conjunction with successively positioning the respective MRAM dies by rotating the chuck (e.g., chuck 202, FIG. 2) and translating the chuck along a single translational axis (e.g., using the stage system 200, FIG. 2).

For each of the respective MRAM dies, rotation of the polarization of the laser beam (e.g., of the plane of polarization of the laser beam) as reflected by the MRAM die is measured (826). MOKE measurements are thus performed. In some embodiments, the detector 122 (FIG. 1) or 522 (FIG. 5) includes an analyzer that is used to measure the rotation of the polarization of the laser beam as reflected by the MRAM die.

In some embodiments (e.g., which include step 824), a detector (e.g., detector 522, FIG. 5) used to measure the rotation of the polarization of the laser beam as reflected by the respective MRAM dies is rotated (828) in accordance with the rotating of the laser and the polarizer.

While the method 800 includes a number of operations that appear to occur in a specific order, the method 800 can include more or fewer operations. Some operations can be executed serially or in parallel. The order of two or more non-order-dependent operations may be changed, performance of two or more operations may overlap, and two or more operations may be combined into a single operation. For example, step 806 may include positioning the MRAM wafer in the magnet before the magnetic field is generated, such that the MRAM wafer is in the desired position when the magnetic field is generated (e.g., by applying current to the coils 106-1 and 106-2, FIG. 1 or 5) in step 804.

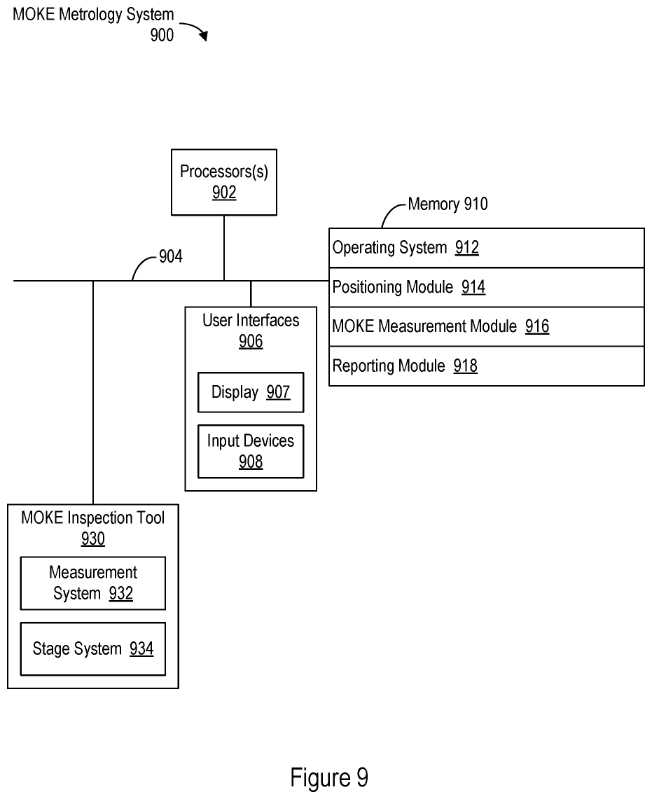

FIG. 9 is a block diagram of a MOKE metrology system 900 in accordance with some embodiments. The MOKE metrology system 900 includes a MOKE inspection tool 930 and a computer system with one or more processors 902 (e.g., CPUs), user interfaces 906, memory 910, and communication bus(es) 904 interconnecting these components. The computer system alternatively may be communicatively coupled with the MOKE inspection tool 930 through one or more networks. The computer system may further include one or more network interfaces (wired and/or wireless, not shown) for communicating with the MOKE inspection tool 930 and/or remote computer systems.

The MOKE inspection tool 930 includes a measurement system 932 (e.g., MOKE measurement system 100, FIG. 1, or 500, FIG. 5) and a stage system 934 (e.g., stage system 200, FIG. 2, or 400, FIG. 4). In some embodiments, the measurement system 932 is the MOKE measurement system 100 (FIG. 1) and the stage system 934 is the stage system 400 (FIG. 4). In some other embodiments, the measurement system 932 is the MOKE measurement system 500 (FIG. 5) and the stage system 934 is the stage system 200 (FIG. 2).

The user interfaces 906 may include a display 907 and one or more input devices 908 (e.g., a keyboard, mouse, touch-sensitive surface of the display 907, etc.). The display 907 may display MOKE measurement results (e.g., results of the method 800, FIG. 8). For example, the display 907 may display curves of the types shown in FIGS. 6 and 7.

Memory 910 includes volatile and/or non-volatile memory. Memory 910 (e.g., the non-volatile memory within memory 910) includes a non-transitory computer-readable storage medium. Memory 910 optionally includes one or more storage devices remotely located from the processors 902 and/or a non-transitory computer-readable storage medium that is removably inserted into the computer system. In some embodiments, memory 910 (e.g., the non-transitory computer-readable storage medium of memory 910) stores the following modules and data, or a subset or superset thereof: an operating system 912 that includes procedures for handling various basic system services and for performing hardware-dependent tasks, a positioning module 914 for causing the stage system 934 to position MRAM dies in the magnet of the measurement system 932 to receive a laser beam with a common orientation with respect to the polarization of the laser beam, a MOKE measurement module 916 for causing the measurement system 932 to take MOKE measurements, and a reporting module 920 for reporting MOKE measurement results (e.g., curves such as the curves in FIGS. 6 and 7) (e.g., results of the method 800, FIG. 8). The memory 910 (e.g., the non-transitory computer-readable storage medium of the memory 910) (e.g., the positioning module 914 together with the MOKE measurement module 916) may include instructions for performing all or a portion of the method 800 (FIG. 8).

Each of the modules stored in the memory 910 corresponds to a set of instructions for performing one or more functions described herein. Separate modules need not be implemented as separate software programs. The modules and various subsets of the modules may be combined or otherwise re-arranged. In some embodiments, the memory 910 stores a subset or superset of the modules and/or data structures identified above.

FIG. 9 is intended more as a functional description of various features that may be present in a MOKE metrology system than as a structural schematic. For example, the functionality of the computer system in the MOKE metrology system 900 may be split between multiple devices. A portion of the modules stored in the memory 910 may alternatively be stored in one or more other computer systems communicatively coupled with the computer system of the MOKE metrology system 900 through one or more networks.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A metrology tool, comprising:
a magnet to generate a magnetic field;
a stage system to position a plurality of magnetic random-access memory (MRAM) dies on an MRAM wafer in the magnetic field, the stage system comprising a chuck on which to mount the MRAM wafer;
optics to provide a laser beam and direct the laser beam to be incident upon respective MRAM dies on the MRAM wafer with the respective MRAM dies positioned in the magnetic field, the laser beam having a polarization; and
a detector to receive the laser beam as reflected by the respective MRAM dies on the MRAM wafer and to measure rotation of the polarization of the reflected laser beam;
wherein the metrology tool is configurable to provide each MRAM die on the MRAM wafer with a common orientation with respect to the polarization of the laser beam when the laser beam is incident on the MRAM die with the MRAM die positioned in the magnetic field.

2. The tool of claim 1, wherein:
the chuck has a rotational axis;
the stage system has a first translational axis and a second translational axis; and
the stage system is configured to translate the chuck along the first and second translational axes and rotate the chuck about the rotational axis to position each MRAM die on the MRAM wafer to have the common orientation with respect to the polarization of the laser beam.

3. The tool of claim 2, wherein the staging system further comprises:
a first translational stage, to which the chuck is coupled, to translate the chuck along the first translational axis;
a first motor to move the first translational stage along the first translational axis;
a second translation stage, to which the first translational stage is coupled, to translate the chuck and the first translational stage along the second translational axis;
a second motor to move the second translational stage along the second translational axis; and
a third motor to rotate the chuck about the rotational axis.

4. The tool of claim 2, wherein the first and second translational axes are perpendicular.

5. The tool of claim 1, wherein:
the magnet is configured to generate the magnetic field to be normal to the respective MRAM dies on the MRAM wafer when the respective MRAM dies are positioned in the magnetic field; and
the optics are configured to direct the laser beam to be normally incident upon the respective MRAM dies on the MRAM wafer when the respective MRAM dies are positioned in the magnetic field.

6. The tool of claim 1, wherein:
the optics comprise a laser to generate the laser beam, a polarizer to polarize the laser beam with the polarization, and mirrors to steer the laser beam to be incident upon the respective MRAM dies on the MRAM wafer; and
the detector comprises an analyzer.

7. The tool of claim 6, wherein:
the laser and polarizer are rotatable about their respective longitudinal axes to vary the polarization of the laser beam; and
the detector is rotatable in accordance with rotation of the laser and polarizer.

8. The tool of claim 7, wherein:
the chuck has a rotational axis;
the stage system has a first translational axis; and
the stage system is configured to translate the chuck along the first axis and rotate the chuck about the rotational axis to position each MRAM die on the MRAM wafer to receive the laser beam.

9. A method, comprising, in a metrology tool:
generating a magnetic field;
positioning a magnetic random-access memory (MRAM) wafer in the magnetic field, the MRAM wafer comprising a plurality of MRAM dies;
with the MRAM wafer positioned in the magnetic field, providing a laser beam to be incident upon the MRAM wafer, the laser beam having a polarization;
successively positioning respective MRAM dies on the MRAM wafer so that the laser beam is successively incident on the respective MRAM dies while the respective MRAM dies are positioned in the magnetic field, comprising orienting each of the respective MRAM dies with a common orientation with respect to the polarization of the laser beam when the laser beam is incident on the MRAM die; and
for each of the respective MRAM dies, measuring rotation of the polarization of the laser beam as reflected by the MRAM die.

10. The method of claim 9, wherein successively positioning the respective MRAM dies comprises successively positioning each MRAM die on the MRAM wafer so that the laser beam is successively incident on each MRAM die while the MRAM die is positioned in the magnetic field and oriented with a common orientation with respect to the polarization of the laser beam.

11. The method of claim 9, further comprising mounting the MRAM wafer on a chuck, wherein successively positioning the respective MRAM dies comprises:
rotating the chuck; and
translating the chuck along a first translational axis and along a second translational axis.

12. The method of claim 11, wherein the first and second translational axes are perpendicular.

13. The method of claim 9, wherein:
providing the laser beam comprises directing the laser beam to be normally incident on the respective MRAM dies; and
generating the magnetic field comprises configuring the magnetic field to be normal to the respective MRAM dies.

14. The method of claim 9, wherein providing the laser beam comprises:
generating the laser beam using a laser; and
polarizing the laser beam to have the polarization, using a polarizer.

15. The method of claim 14, wherein the orienting comprises rotating the laser and the polarizer about their respective longitudinal axes to vary the polarization.

16. The method of claim 15, wherein successively positioning the respective MRAM dies comprises:
rotating the chuck; and
translating the chuck along a single translational axis.

17. The method of claim 15, wherein:
the measuring is performed using a detector; and
the method further comprises rotating the detector in accordance with the rotating of the laser and the polarizer.

18. A metrology tool, comprising:
a magnet to generate a magnetic field;
a stage system to position a plurality of magnetic random-access memory (MRAM) dies on an MRAM wafer in the magnetic field, the stage system comprising a chuck on which to mount the MRAM wafer;
optics to provide a laser beam and direct the laser beam to be incident upon respective MRAM dies on the MRAM wafer with the respective MRAM dies positioned in the magnetic field, the laser beam having a polarization; and
a detector to receive the laser beam as reflected by the respective MRAM dies on the MRAM wafer and to measure rotation of the polarization of the reflected laser beam;
one or more processors; and
memory storing one or more programs for execution by the one or more processors, the one or more programs comprising instructions for providing each MRAM die on the MRAM wafer with a common orientation with respect to the polarization of the laser beam when the laser beam is incident on the MRAM die with the MRAM die positioned in the magnetic field.
